(19) United States
(12) Patent Application Publication
(10) Pub. No.: US 2026/0190929 A1
(43) Pub. Date: Jul. 2, 2026

(54) Cassette for Vapor Processing Chamber

(71) Applicant: Applied Materials, Inc., Santa Clara, CA (US)

(72) Inventors: Andrew Nguyen, Gilbert, AZ (US); Ajit Balakrishna, Sunnyvale, CA (US); Sue-Ann Yow, Mesa, AZ (US); Eric Liu, Tempe, AZ (US); Vijayabhaskara Venkatagiriyappa, Bangalore (IN)

(73) Assignee: Applied Materials, Inc., Santa Clara, CA (US)

(21) Appl. No.: 19/003,394

(22) Filed: Dec. 27, 2024

(51) Int. Cl. H01L 21/673; H01L 21/677

(52) U.S. Cl. CPC H10P 72/1921; H10P 72/3218

(57) ABSTRACT

Wafer cassette configured for a vapor processing chamber, a vapor processing chamber comprised the wafer cassette and deposition methods using the wafer cassette are described. The wafer cassette comprises a base plate with a support upright on a top surface thereof. The support upright has a plurality of spaced apart support plates. Each support plate has a flat inlet end and an outlet end with a circular segment cutout. The circular segment cutout extends in the range of 160° to 230°.

### TECHNICAL FIELD

Embodiments of the disclosure are directed to wafer support structures for semiconductor batch processing chambers. In particular, embodiments of the disclosure are directed to shaped cassettes to vertically support multiple wafers in semiconductor batch processing chambers.

### BACKGROUND

Reliably producing submicron and smaller features is one of the key requirements of very large scale integration (VLSI) and ultra large scale integration (ULSI) of semiconductor devices. However, with the continued miniaturization of circuit technology, the dimensions of the size and pitch of circuit features, such as interconnects, have placed additional demands on processing capabilities. The various semiconductor components (e.g., interconnects, vias, capacitors, transistors) require precise placement of high aspect ratio features. Reliable formation of these components is critical to further increases in device and density.

Additionally, the electronic device industry and the semiconductor industry continue to strive for larger production yields while increasing the uniformity of layers deposited on substrates having increasingly larger surface areas. To increase production yields, batch processing chambers have been developed that can process multiple wafers at one time.

Some batch processing chambers use a flow of reactive gas across the surfaces of multiple wafers. Current batch processing chambers allow films to be deposited on the front side and back side of the wafer. FIG. 1A illustrates a cross-sectional schematic view of a prior art vertically stacked batch processing chamber 10. FIG. 1B illustrates a top view of the vertically stacked batch substrate (or wafer) processing chamber 10 of FIG. 1A showing the flow of gases in the chamber. In the vertically stacked batch processing chambers 10, wafers 12 are positioned on supports 14 in a spaced apart arrangement. A gas 16 is injected into the wafer processing chamber 10 from a gas inlet 18 including a first gas inlet port 18a and a second gas inlet port 18b, causing a first gas and a second gas to flow across the surface of the wafers 12, as illustrated in FIG. 1B. This type of gas injection deposits a film on the top surface 12a of the wafer 12, however, non-uniformity of the deposited films across the surface of each of the wafers 12 in vertically stacked batch processing chambers 10 tends to be higher and does not meet film uniformity specifications compared to deposition uniformity achieved in single wafer vapor deposition chambers.

Accordingly, there is a need in the art for apparatus and methods for the batch deposition of films on a wafer more uniform deposition across the top surface 12a of the wafers.

### SUMMARY

One or more embodiments of the disclosure are directed to a wafer cassette configured for a vapor processing chamber, in particular for a batch vapor processing chamber that is configured to simultaneously process a batch of wafers. The wafer cassette includes a base plate and a support upright. The support upright is on a top surface of the base plate. The support upright has a plurality of spaced apart support plates. Each support plate has a flat inlet end and an outlet end with a circular segment cutout extending in the range of 160° to 230°.

Additional embodiments of the disclosure are directed to a vapor deposition processing chamber including a reaction chamber and a wafer cassette. The reaction chamber has a top wall, sidewalls with an inlet end and an outlet end, with an opening in a bottom wall. The wafer cassette includes a base plate and a support upright on a top surface of the base plate. The support upright has a plurality of spaced apart support plates. Each support plate has a flat inlet end, and an outlet end with a circular segment cutout extending in the range of 160° to 230°. The base plate of the wafer cassette seals the opening in the bottom wall of the reaction chamber.

Further embodiments of the disclosure are directed to a method of improving gas flow uniformity is a cross-flow batch processing chamber. The method includes positioning a wafer cassette into the processing chamber and flowing a process gas from an inlet of the processing chamber. The wafer cassette includes a base plate and a support upright on a top surface of the base plate. The support upright has a plurality of spaced apart support plates. Each support plate has a flat inlet end, and an outlet end with a circular segment cutout extending in the range of 160° to 230°. The process gas is flowed from an inlet of the processing chamber across and through a gap between the spaced apart support plates to an outlet of the processing chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate embodiments of this disclosure and are therefore not to be considered limiting of its scope, for the disclosure may admit to other equally effective embodiments.

FIG. 1A illustrates a cross-sectional schematic view of a prior art vertically stacked batch wafer processing chamber;

FIG. 1B illustrates a top view of the prior art vertically stacked batch processing chamber of FIG. 1A showing the flow of gases in the chamber;

FIG. 2 illustrates a schematic cross-sectional view of a vertically stacked batch wafer processing chamber according to one or more embodiments of the disclosure;

FIG. 3 illustrates a schematic cross-sectional view of a portion of a vertically stacked batch processing chamber illustrating gas flows according to one or more embodiments of the disclosure;

FIG. 4 shows a schematic top view of a vertically stacked batch wafer processing chamber illustrating loading/unloading of the wafers according to one or more embodiments of the disclosure;

FIG. 5 illustrates a schematic partial cross-sectional view of a wafer being lifted off the plurality of wafer supports by a lift pin according to one or more embodiments of the disclosure;

FIG. 6 illustrates a transparent processing chamber (also called a reactor) according to one or more embodiments of the disclosure;

FIG. 7 shows a cross-sectional view of the processing chamber 200 of FIG. 6 taken along line 7-7′ of FIG. 6;

FIG. 8 shows a velocity plot using computation flow dynamics with an advanced Multiphysics simulation platform according to one or more embodiment of the disclosure;

FIG. 9 shows a thickness plot of a film deposited on a wafer with a thicker film at the edges than the center;

FIG. 10 illustrates a transparent view of a processing chamber with vertically stacked wafers supported on a wafer cassette in which each of the support plates 405 has a medial portion and a proximal end portion, with an open distal end portion according to one or more embodiments of the disclosure;

FIG. 11 shows a cross-sectional view of the processing chamber of FIG. 10 taken along line 11-11′;

FIG. 12 illustrates an isometric view of a wafer cassette in accordance with one or more embodiments of the disclosure;

FIG. 13 shows an expanded view of region XIII of FIG. 12;

FIG. 14 illustrates a velocity plot using computation flow dynamics with an advanced Multiphysics simulation platform showing that the wafer cassette of embodiments of the disclosure increase the uniformity of the flow across the center of the wafer relative to the sides of the wafers;

FIG. 15A illustrates a schematic top view of a vertically stacked batch wafer processing chamber illustrating a rectangular-ended wafer cassette according to one or more embodiments of the disclosure; and

FIG. 15B illustrates a schematic side view of the vertically stacked batch wafer processing chamber of FIG. 15A.

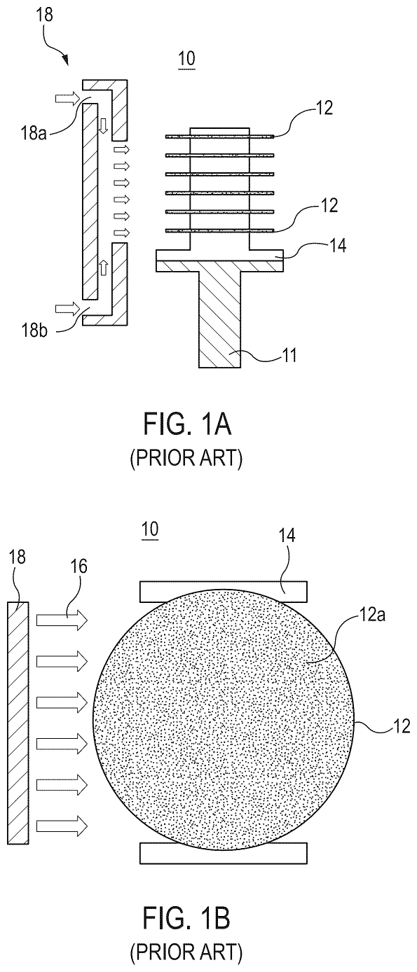

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon

A “substrate” and a “wafer” as used herein, refers to any substrate, wafer or material surface formed on a substrate upon which film processing is performed during a fabrication process. For example, a substrate surface or wafer surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

“Atomic layer deposition” or “cyclical deposition” as used herein refers to a process comprising the sequential exposure of two or more reactive compounds to deposit a layer of material on a substrate surface. “Atomic layer deposition” or “cyclical deposition” as used herein refers to a process comprising the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas. The gas curtain can be any suitable gas separation arrangement known to the skilled artisan. For example, in some embodiments of a spatial ALD process chamber, a gas curtain is formed by a combination of purge gas ports and vacuum ports to maintain separation between the reactive gases to prevent gas-phase reactions. In some embodiments of a spatial ALD process chamber, separate process stations are configured to form a mini-process environment within each station.

As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction, cycloaddition). The substrate, or portion of the substrate, is exposed sequentially to the two or more reactive compounds which are introduced into a reaction zone of a processing chamber.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of “about.”

Spatially relative terms, such as “beneath,” “below,” “lower,” “above,” “upper” and the like, may be used herein for ease of description to describe one element or feature's relationship to another element(s) or feature(s) as illustrated in the Figures. It will be understood that the spatially relative terms are intended to encompass different orientations of a device in use or operation in addition to the orientation depicted in the figures. For example, if the device in the Figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

One or more layers deposited on the substrate or substrate surface by atomic layer deposition (ALD) or plasma-enhanced atomic layer deposition (PEALD) are conformal. As used herein, as will be understood by the skilled artisan, a layer which is “conformal” or “conformally deposited” refers to a layer where the thickness is about the same throughout. A layer/film which is conformal varies in thickness by less than or equal to about 5%, 2%, 1% or 0.5%.

One or more embodiments of the disclosure are directed to wafer batch processing chambers that provide more uniform deposition on the wafer compared to existing wafer batch processing chambers. Multiple gas injection ports to deliver gas to individual wafers in the batch processing chamber provides enhances full wafer coverage of the process gas and the film deposited on the wafers. In one or more embodiments, multiple gas exhaust ports for the batch process chamber are configured to nullify dead legs inside the chamber, minimizing unwanted deposition. According to some embodiments, complicated rotary mechanisms to rote the substrates during a deposition process are not required to provide more uniform deposition. According to one or more embodiments, wafer processing times are reduced. Fewer moving parts are needed compared to existing wafer batch processing chamber. In some embodiments, sequential operation of process gas inlet and outlets increase wafer deposition efficiency and uniformity. Control of process gas flows into the inlets that are peripherally spaced at different locations of the wafer processing chamber as well as gas outlets that are also peripherally spaced at different locations of the wafer processing chamber with the use of gas valves and a controller provides for strategic and precise gas flows to regulate process gas flow and improve deposition uniformity.

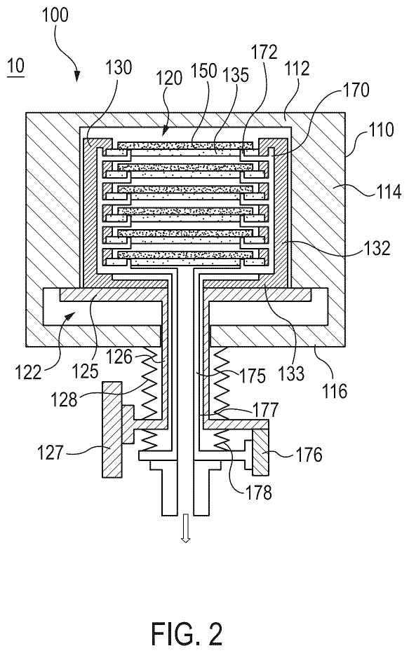

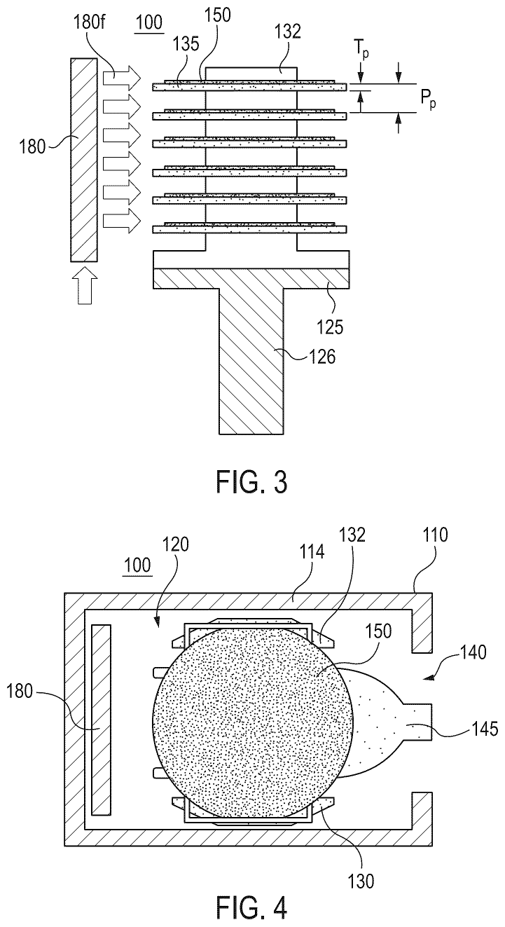

FIG. 2 illustrates a schematic cross-sectional view of a wafer processing chamber 100 configured to deposit films simultaneously on a plurality of substrate according to one or more embodiments of the disclosure. FIG. 3 illustrates a schematic cross-sectional view of a portion of the wafer processing chamber 100 illustrating gas flows to each substrate in the stack of substrates. FIG. 4 shows a schematic top view of a wafer processing chamber 100 illustrating loading/unloading of the wafers. The wafer processing chamber 100 has a reaction chamber 110 with a top 112, a sidewall 114 and a bottom 116. The reaction chamber 110 defines an inner chamber region 120 and an outer chamber region 122.

The wafer processing chamber 100 includes a wafer cassette assembly 130 inside the reaction chamber 110. The wafer cassette assembly 130 comprises at least two support columns 132 configured to hold a plurality of wafers 150, or a plurality of wafer supports 135 spaced along a height of the at least two support columns 132. The wafer cassette assembly 130 of some embodiments further comprises one or more of a floor 133 or ceiling (not shown). The embodiment illustrated in FIGS. 2 and 3 show six wafers 150 on six wafer supports 135. The skilled artisan will recognize that there can be any suitable number of wafers 150 and wafer supports 135 was indicated herein, for example 25 or more wafers. In some embodiments, there are in the range of 5 to 50 wafer supports 135, or in the range of 15 to 25 wafer supports 135.

The wafer cassette assembly 130 and wafer supports 135 can be made of any suitable material known to the skilled artisan. In some embodiments, the wafer cassette assembly 130 (including at least two support columns 132) and/or the plurality of wafer supports 135 comprise aluminum.

The wafer processing chamber 100 further comprises at least one lift pin assembly 170 comprising a plurality of lift pins 172. The plurality of lift pins 172 are arranged so that each of the plurality of wafer supports 135 comprises at least three lift pins 172. The skilled artisan will recognize that three points define a planar surface, and as the wafer 150 is a planar surface, three points of contact (i.e., by three lift pins) are used to prevent destabilization of the wafer 150 during loading/unloading operations.

The lift pins 172 (and optionally the lift pin assembly 170) can be made of any suitable material. In some embodiments, the plurality of lift pins 172 and/or at least one lift pin assembly 170 comprise a dielectric material. For example, suitable materials for the plurality of lift pins 172 and/or the at least one lift pin assembly 170 include, but are not limited to, ceramic.

As shown in FIG. 4, the sidewall 114 of the reaction chamber 110 comprises a slit valve 140 to allow a wafer 150 to be loaded or unloaded from the wafer processing chamber 100. In some embodiments, the slit valve 140 is located in the inner chamber region 120 of the reaction chamber 110 to load and unload wafers 150 from the wafer cassette 160. FIG. 4 illustrates a wafer 150 on a robot 145 extending through the open slit valve 140. The illustration shows the slit valve 140 without a door, however, the skilled artisan will recognize that the slit valve 140 of some embodiments has a door that can be opened and closed to isolate inner chamber region 120 from the conditions outside of the reaction chamber 110.

In the illustrated embodiment, the wafer cassette assembly 130 sits on a pedestal 125 connected to a pedestal lift assembly 126. The pedestal lift assembly 126 includes an actuator 127 (also referred to as a motor) configured to move the pedestal 125 along the height of the stack of wafers 150. Suitable actuators 127 include, but are not limited to, linear guides and servo motors or stepper motors. A bellows 128, or other suitable vacuum isolator, connects the pedestal lift assembly 126 with the reaction chamber 110 to maintain vacuum within the reaction chamber 110.

In some embodiments, the pedestal 125 acts as a cathode. For example, in a plasma-enhanced deposition process, the pedestal 125 acts as the cathode with a different component in the wafer processing chamber 100 acting as the anode to generate a plasma within the inner chamber region 120.

The at least one lift pin assembly 170 of some embodiments, further comprises a lift mechanism 175. The lift mechanism 175 can be used to move the at least one lift pin assembly 170 between the inner chamber region 120 and outer chamber region 122 of the reaction chamber 110. In the illustrated embodiment, the lift mechanism 175 includes an actuator 176 (also referred to as a motor). Suitable actuators 176 include, but are not limited to, linear guides and servo motors or stepper motors. In some embodiments, the actuator 176 is mounted to the pedestal lift assembly 126 and a bellows 178 (or other suitable vacuum isolator) connects the pedestal lift assembly 126 to the lift pin assembly 170 lift mechanism 175.

In the illustrated embodiment, the lift mechanism 175 includes a hollow shaft 177. The hollow shaft 177 of some embodiments is connected to a fore line or vacuum pump to maintain reduced pressure in the wafer processing chamber 100.

The wafer processing chamber 100 of some embodiments includes a gas injector 180. The gas injector 180 is not visible in the embodiment illustrated in FIG. 2 due to the angle of the view shown. However, a side view and top view showing the gas injector 180 can be found in FIGS. 3 and 4, respectively. The gas injector 180 is configured to provide a flow of gas across the surface of the plurality of wafer supports 135.

In some embodiments, the pedestal 125 further comprises a heater (not shown). In some embodiments, the heater has one heating element. In some embodiments, there is more than one heating element. Multiple heating elements can be arranged in any suitable manner. In some embodiments, the heating elements are arranged in radial zone.

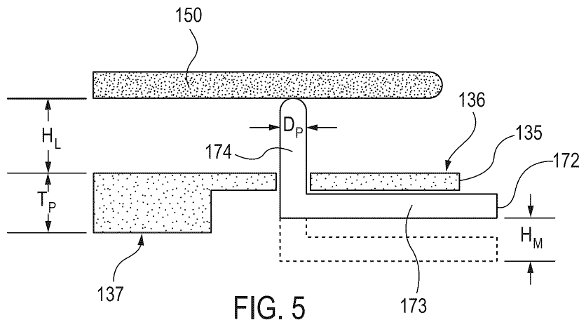

FIG. 5 illustrates a schematic partial cross-sectional view of a wafer 150 being lifted off the plurality of wafer supports 135 by a lift pin 172. Referring to FIGS. 3 and 5, the thickness T_{P} of the plurality of wafer supports 135 measured from the top surface 136 to the bottom surface 137 is in the range of 1 mm to 5 mm or in the range of 1.5 mm to 2.5 mm. The thickness is measured as the thickest portion of the plurality of wafer supports 135 that will be vertically oriented with a wafer 150 during processing. For example, the outer peripheral portions of the plurality of wafer supports 135 outside the diameter of the wafer 150 are not considered in this measurement.

In some embodiments, the pitch Pp between the top surfaces 136 of adjacent wafer supports 135 is in the range of 5 mm to 20 mm, or in the range of 7.5 mm to 15 mm, or in the range of 10 mm to 12 mm. In some embodiments, the pitch PP is greater than or equal to 5 mm, 6 mm, 7 mm, 8 mm or 9 mm, and less than or equal to 50 mm, 45 mm, 40 mm, 35 mm, 30 mm, 25 mm, 20 mm, or 15 mm.

Referring to FIG. 5, in some embodiments, the lift pin 172 comprises a pin arm 173 and a pin portion 174. In use, the height HM that the lift pin 172 can move is in the range of 2 mm to 10 mm, or in the range of 3 mm to 8 mm, or in the range of 4 mm to 7 mm, or in the range of 5 mm to 6 mm. The height HM that the lift pin 172 moves depends on, for example, the length of the pin portion of the lift pin 172 and the thickness of the robot 145 end effector. The height H_{L} that the wafer 150 is lifted above the top surface 136 of the plurality of wafer supports 135 during loading/unloading is equal to or less than the height HM that the lift pin 172 can move.

The diameter D_{P} of the pin portion 174 of the lift pin 172 in some embodiments, is in the range of 1 mm to 10 mm, or in the range of 2 mm to 8 mm, or in the range of 3 mm to 6 mm. The contact end of the pin portion 174 can be any suitable shape including, but not limited to, squared, rounded or tapered.

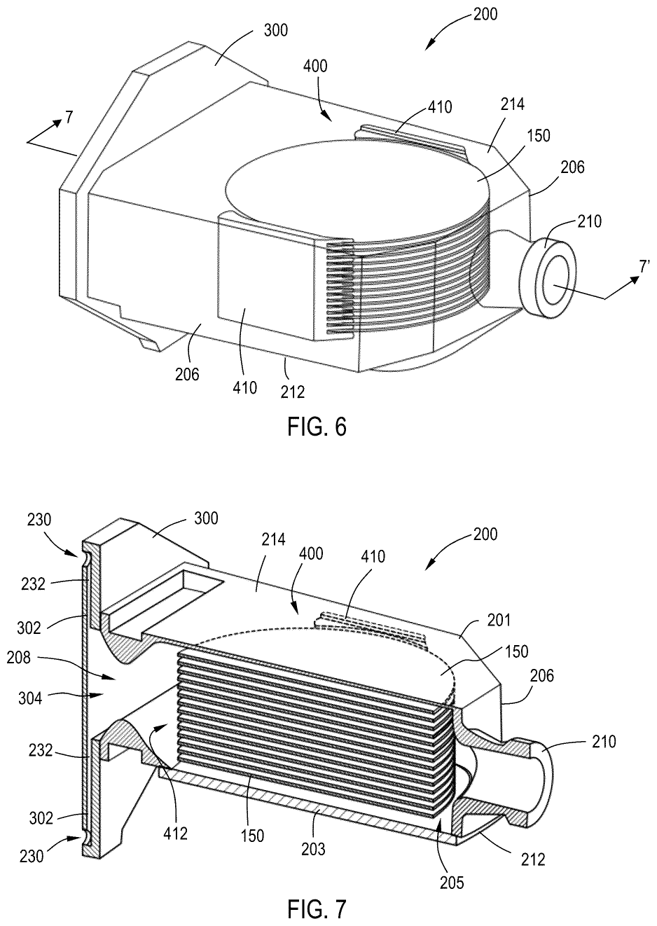

FIGS. 6 and 7 illustrate a batch processing chamber that processes multiple wafers 150 arranged in a vertical stack. FIG. 6 illustrates a transparent processing chamber 200 (also called a reactor) according to one or more embodiments of the disclosure. The embodiment of FIG. 6 is transparent to allow for a view of the interior of the processing chamber. This is merely for descriptive purposes and should not be taken as limiting the scope of the disclosure. FIG. 7 shows a cross-sectional view of the processing chamber 200 of FIG. 6 taken along line 7-7′ of FIG. 6.

The processing chamber 200 comprises a fluid distributing device 300 configured to generate a laminar flow of fluid throughout a reaction space (the interior 205 of the processing chamber) incorporating a plurality of wafers 150. The processing chamber 200 comprises a reaction chamber 201 and a fluid distributing device 300 with an expansion region 302 and a transition region 304, the latter connecting the expansion region 302 with the interior 205 of the reaction chamber 201.

The reaction chamber 201 of some embodiments is configured as an elongated vessel with an interior 205 that accommodates a plurality of wafers 150. In some embodiments, the plurality of wafers 150 are arranged into a vertical stack.

The wafers 150 can be loaded into the reaction chamber 201 one by one or as a batch using a wafer cassette 400. In a non-limiting manner, a wafer cassette 400 can be configured for to support a batch of wafers 150 for processing. In some embodiments, the batch of wafers 150 comprises in the range of 2 to 30 wafers. In some embodiments, the wafer cassette 400 is configured to support in the range of 5 to 25 wafers, or in the range of 10 to 20 wafers 150 for processing.

In some embodiments, the wafer cassette 400 can be integrated with a door or hatch with the reaction chamber 201. In some embodiments, the wafer cassette 400 is a separate, removable part.

The reaction chamber 201 is configured to closely fit around a batch of wafers received thereinto. Thus, in some embodiments, the outermost edge of the wafers 150 in the batch are distanced from the lateral walls 206 by essentially the same distance as provided between all wafers 150 in the batch.

In one or more embodiments, fluid(s) propagate through the reaction chamber 201 along its longitudinal plane. Longitudinal plane of the reaction chamber is the plane that passes from the entrance 208 of the reaction chamber 201 to its tail (exhaust port 210). In present disclosure, the direction from head to tail is referred to as y-direction or a direction along the Y-axis (a longitudinal axis). Fluid flow through the reaction chamber is thus referred to as occurring along the longitudinal plane independent of whether the processing chamber 200 is positioned vertically or horizontally.

Wafers 150 are loaded into the reaction chamber 201 via an opening typically shut with the door 203. Any face of the reaction chamber can be provided with the opening for substrate loading. Depending on whether the processing chamber 200 is arranged vertically or horizontally, loading can be implemented from the side through lateral walls 206, from the bottom wall 212 or from the top wall 214. The processing chamber 200 further comprises an exhaust port 210 for discharging an exhaust flow, such as excess carrier, precursor and reaction products, out of the interior 205 of the reaction chamber 201. The exhaust port 210 can be connected to a fore-line or a pump unit and optionally one or more valves (not shown). The skilled artisan will be familiar with the arrangement of components and valves for exhausting a processing chamber.

Reactive gas fluids are delivered into the reaction chamber 201 via a number of intake openings 230. While not shown, the skilled artisan will recognize that the intake openings 230 can be connected to one or more or plumbing or valves to provide a suitable fluid flow. For example, a gas manifold can be connected to one or more of the intake openings 230 through one or more valves. FIGS. 6 and 7 are illustrative of an embodiment in which precursor fluid is delivered inside the reaction chamber 201 by means of at least one feedline 232. In the illustrated embodiment, there are two feedlines 232. In some embodiments, it is preferred that the processing chamber 200 comprises two, three or more feedlines 232. In some configurations, the apparatus may comprise a manifold feedline and a distributing pipework connectable to a variety of precursor sources and an inert gas supply or supplies (not shown).

Precursor(s) are delivered into the feedline 232 in a fluidic form. Precursor(s) are supplied into the feedline 232 from a supply source (not shown) or sources configured as containers, ampoules, cartridges or a piping system, for example. A variety of precursor chemicals required for deposition reaction(s), such as ALD reaction(s), can be directed into the reaction space via a single feedline 232.

With reference to FIG. 7, reactive fluid(s) are delivered into the reaction chamber 201 via a number of inlets (intake openings 230) connected to the at least one feedline 232. The transition region 304 (also called the “throat”) is established between the expansion region 302 and the reaction chamber 201. In the processing chamber 200, the transition region 304 is a zone, where the fluid streams arriving from essentially opposite sides converge and mix. In terms of its shape and/or a variety of structural appliances, the transition region 304 is configured to receive and to combine fluid streams arriving thereto via the expansion region 302, whereby a combined fluid stream is formed, which is further directed into the interior 205 of the reaction chamber 201 to flow across the surfaces of the wafers 150.

In the embodiment illustrated in FIGS. 6 and 7, the wafer cassette 400 includes at least two support columns 410 positioned on opposite sides of the plurality of wafers 150. This leaves an unsupported center portion 412 of each plurality of wafer supports. The gap between the support columns forming the unsupported center portion 412 can be used to allow for unrestricted access by the robot blades for loading/unloading operations.

Process chambers like that shown in FIGS. 6 and 7 often suffer from non-uniform gas velocity across the wafers. It is believed that this non-uniformity, at least partially, arises from the distance a gas travels from inlet to outlet being greater at the edges of the wafers. The vertically stacked wafers act as parallel plates and appear to obey Poseullie's Law of motion parallel plate as in the equation below

$$v ( x ) = \frac{1}{2 η} \frac{\partial P}{L} [ y ( h - y ) ] for 0 \leq y \leq h .$$

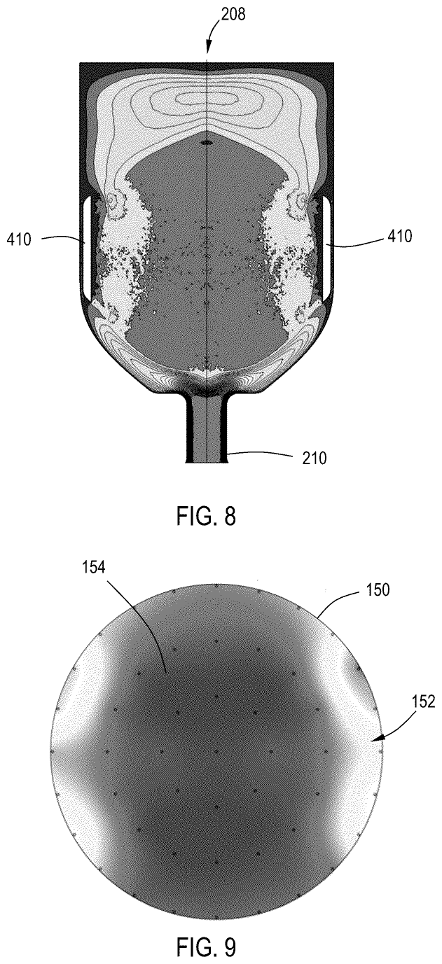

FIG. 8 shows a velocity plot using computation flow dynamics with an advanced Multiphysics simulation platform. The flow across the center of the wafer is generally lower in velocity by two times as the length L is the longest. The velocities at the sides of the wafer are the highest. This means that there are a greater number of species traveling across the side of the wafer at a given time. The at least two support columns 410 of the wafer cassette 400 are illustrated in FIG. 8 as white space. This difference in velocities results in a thicker film 152 deposited at the sides of the wafer 150 and a thinner film 154 deposited in the center of the wafer 150, as shown in FIG. 9.

The inventors have surprisingly found that using a wafer cassette 400 with support plates that include a distal end portion that changes the flow characteristics within the processing chamber. Accordingly, one or more embodiments of the disclosure are directed to wafer cassettes 400 with wafer supports 420. The wafer cassette 400 includes one or more support columns 410 connected by the base plate 430, or floor of the wafer cassette 400.

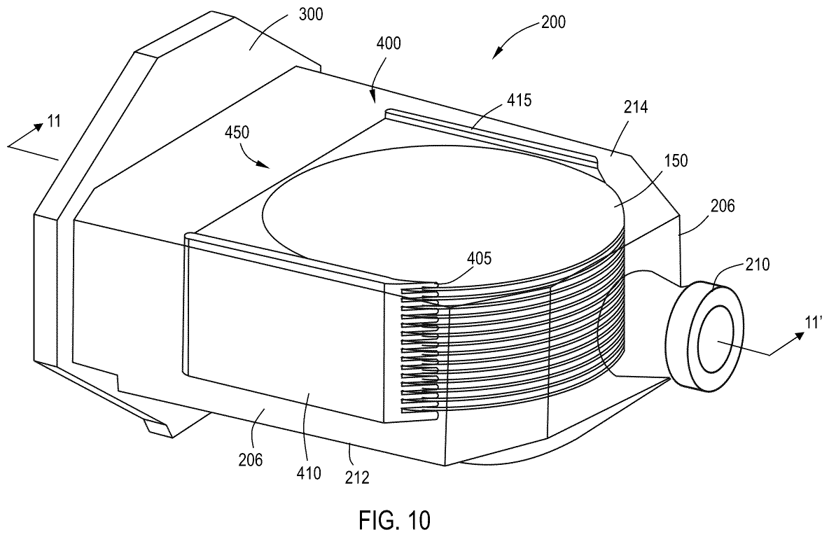

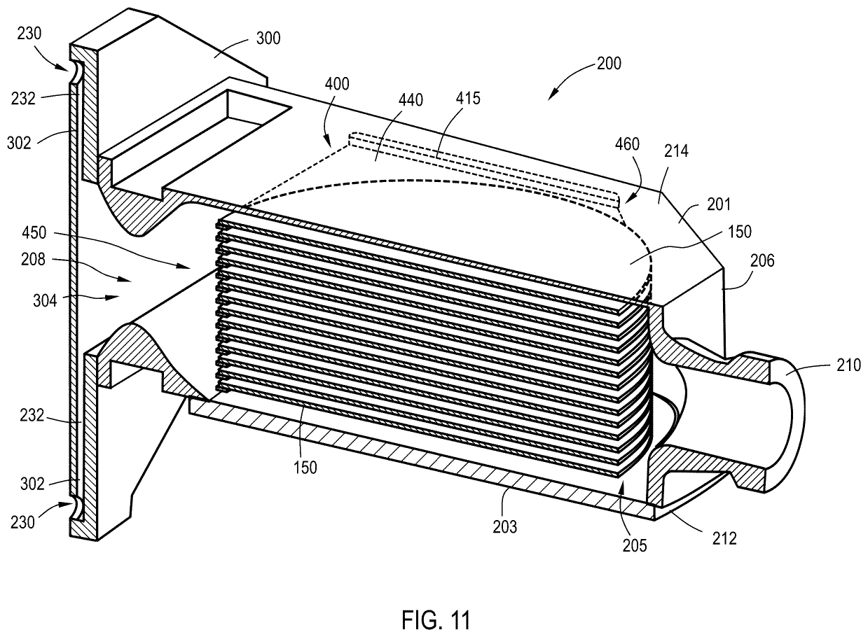

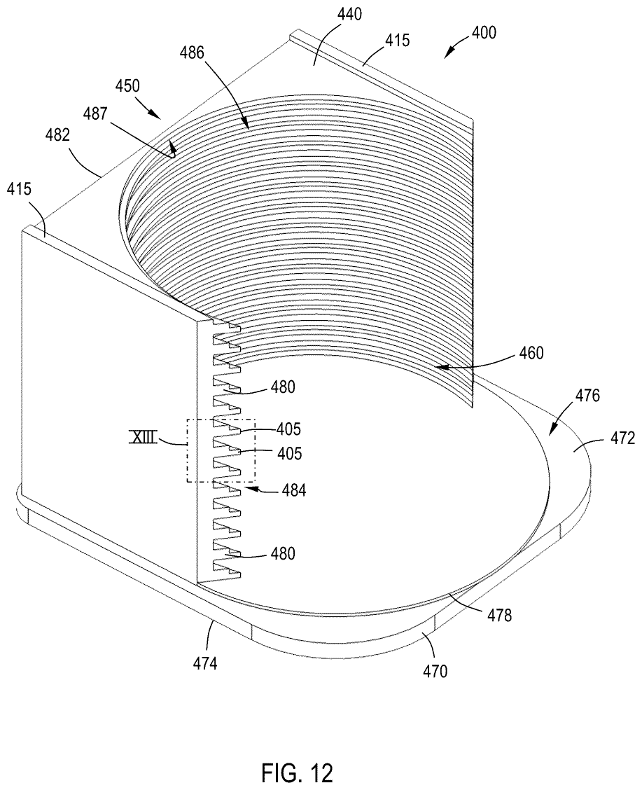

FIG. 10 illustrates a transparent view of a processing chamber 200 with vertically stacked wafers 150 supported on a wafer cassette 400 in which each of the support plates 405 has a medial portion 440 and a proximal end portion 450, with an open distal end portion 460. The use of proximal, medial and distal are relative the flow of fluid passing through the processing chamber. For example, in the embodiment illustrated, fluid flow generally from the left side of the page, the proximal end portion 450, past the medial portion 440 and then the open distal end portion 460 to the exhaust port 210. FIG. 11 shows a cross-sectional view of the processing chamber of FIG. 10 taken along line 11-11′. FIG. 12 illustrates an isometric view of a wafer cassette 400 in accordance with one or more embodiment of the disclosure.

Accordingly, with reference to FIGS. 10 through 12, one or more embodiments of the disclosure are directed to wafer cassettes 400 for a vapor processing chamber 200. The wafer cassette 400 comprises a base plate 470 having a top surface 472 and a bottom surface 474 defining a thickness of the base plate 470. A support upright 415 is on a top surface 472 of the base plate 470. In use, the support uprights 415 extend parallel to the lateral walls 206 of the processing chamber 200. The term “support upright” is used instead of “support column” to illustrate the differences between the wafer cassettes 400 shown in FIGS. 10-12 relative to that of FIGS. 6-7.

The support upright 415 has a plurality of spaced apart support plates 480. Each support plate 480 has a flat inlet end 482 at the proximal end portion 450 and an outlet end 484 with a circular segment cutout 486 at the open distal end portion 460. As used in this manner, a flat end refers to an end of the support plate that has a straight profile and extends perpendicular to the flow of gases within the processing chamber. The medial portion 440 connects the two support uprights 415 to form a single component. The circular segment cutout 486 extending around a circle, or if a wafer was present, around the periphery of the wafer by an amount in the range of 160° to 230°.

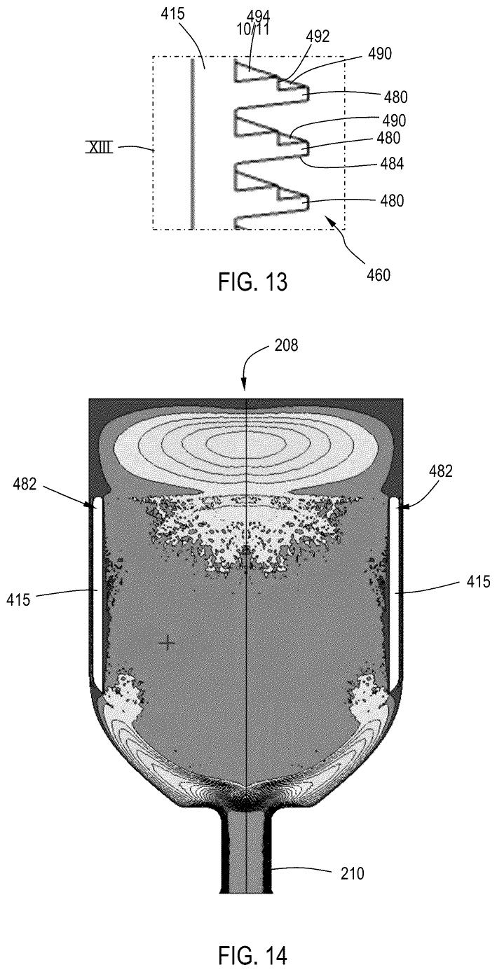

FIG. 13 shows an expanded view of region XIII to illustrate the support plates 480 and spacing therebetween. Each of the support plates 480 is configured to hold an edge of a wafer during processing and allow a flow of gas to pass across a top surface of the wafer. In the illustrated embodiment, each of the support plates 480 has a lower level surface 490 and the upper level surface 494 connected by a vertical wall 492. In some embodiments, a wafer is supported on the lower level surface 490 and the vertical wall 492 is sized so that the upper level surface 494 is substantially coplanar with the top surface of the wafer.

In some embodiments, each of the circular segment cutouts 486 is concentric with the wafer. For example, in some embodiments, the vertical wall 492 is generally circular (with a cutout portion) and is sized to be slightly larger than a wafer. In some embodiments, the diameter of the vertical wall 492 is in the range of 0.2 mm to 5 mm larger than the diameter of a wafer being processed.

The length of the lower level surface 490 is the portion of the support plates 405 that contact the edge of the wafer. In some embodiments, the length of the lower surface 490 is in the range of 1 mm to 20 mm, or in the range of 2 mm to 15 mm, or in the range of 3 mm to 10 mm.

The spacing between the plurality of spaced apart support plates 405 is sufficient to allow a flow of gas to pass across the surface of a wafer. In some embodiments, the vertical distance between the spaced apart support plates 405, or between the lower level surface 490 of each support plates 405 are spaced equidistantly. In some embodiments, the vertical distance between the spaced apart support plates 405 is in the range of 2 mm to 25 mm, or in the range of 3 mm to 20 mm, or in the range of 4 mm to 15 mm, or in the range of 5 mm to 10 mm.

The number of support plates 405 can be any suitable number depending on the size of the processing chamber 200 and the intended number of wafers in any given batch. In some embodiments, there are in the range of 5 to 25 support plates 405.

The support uprights 415 of some embodiments comprise opposing vertical columns along an outer sidewall of the support plates 405. The height of the support uprights 415 depend on the number of support plates 405 and the spacing between the support plates 415, also referred to as the pitch, as described above.

In some embodiments, the flat inlet end 482 is spaced from an apex 487 of the circular segment cutout 486 by a distance less than or equal to 10 mm. In some embodiments, the circular segment cutout 486 extends in the range of 185° to 220°, or in the range of 190° to 215°. In some embodiments, the circular segment cutout 486 extends in the range of greater than or equal to 180° to less than or equal to 260°, or 250° or 240°.

In some embodiments, the top surface 472 of the base plate 470 has a recessed outer edge 476 so that the support upright is positioned on a mesa 478. In some embodiments, the mesa 478 and top surface 472 of the base plate 470 are configured to seal the bottom wall of the processing chamber 200 so that the wafer cassette 400 acts to seal the opening in the bottom wall of the reaction chamber 201.

FIG. 14 illustrates a velocity plot using computation flow dynamics with an advanced Multiphysics simulation platform showing that the wafer cassette of FIG. 12 increases the uniformity of the flow across the center of the wafer relative to the sides of the wafers.

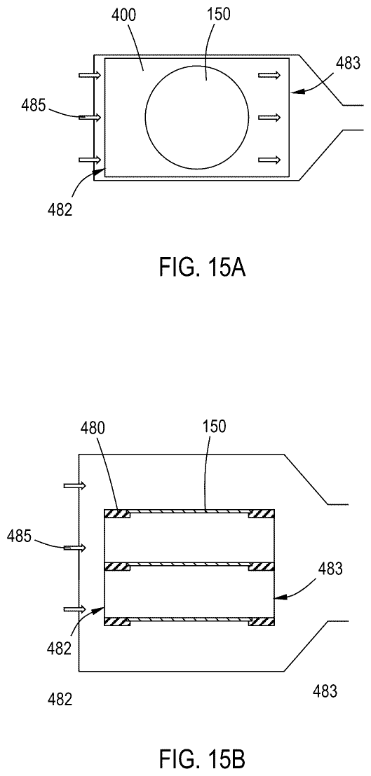

In some embodiments, the wafer cassette 400 is a generally rectangular shaped component having a cuboid appearance (or cubical). For example, the wafer cassette 400 of some embodiments has a flat inlet end 482 and a flat outlet end 483. FIG. 15A illustrates a schematic top view of a vertically stacked batch wafer processing chamber 200 illustrating a rectangular-ended wafer cassette 400 according to one or more embodiments of the disclosure. FIG. 15B illustrates a schematic side view of the vertically stacked batch wafer processing chamber 200 illustrated in FIG. 15A. The wafer cassette 400 illustrated has a plurality of spaced apart support plates 480 with a top plan view that resembles a rectangle with a circular cutout 486 sized to support a wafer 150. In the embodiment illustrated, there are three support plates 480 in the wafer cassette 400 connected by support uprights 415. The support uprights 415 extend substantially parallel to the sidewalls of the processing chamber interior. Each of the spaced support plates 480 has a flat inlet end 482 and a flat outlet end 483. As used in this manner, a flat end is a straight segment that extends perpendicular to the flow 485 of process gases within the interior of the processing chamber.

Some embodiments of the disclosure are directed to methods of improving gas flow uniformity is a cross-flow batch processing chamber. The method comprises positioning a wafer cassette 400 into the processing chamber 200. The wafer cassette 400 comprises a base plate 470, and a support upright 415 on a top surface 472 of the base plate 470. The support upright 415 has a plurality of spaced apart support plates 480. Each support plate 480 has a flat inlet end 482 and an outlet end 484 with a circular segment cutout 486, where the circular segment cutout 486 extends in the range of 160° to 230°. A process gas is flowed from an inlet of the processing chamber across and through a gap between the spaced apart support plates to the exhaust port of the processing chamber. Some embodiments of the disclosure provide methods that have a gas flow uniformity that is greater than with a similar processing chamber using a wafer cassette in which the spaced apart support plates do not have the flat inlet end. In some embodiments, the wafer cassette 400 has support plates 480 with a flat inlet end 482 and a flat outlet end 483 (as shown in FIGS. 15A and 15B). The flat ends extend across the processing chamber perpendicular to the flow of process gas from the inlet of the processing chamber. The support uprights 415 extend along and are parallel to the lateral walls 206 of the reaction chamber 201.

In some embodiments, the wafers 150 positioned on the support plates 480 of the wafer cassette 400 are indexed, or rotated by a predetermined amount during processing. In some embodiments, the wafers 150 are indexed or rotated 180° during processing. Rotation of the wafers 150 can be performed while the process gas is flowing or during a period of time where the process gas is not flowing.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A wafer cassette configured for a vapor processing chamber, the wafer cassette comprising:
a base plate; and
a support upright on a top surface of the base plate, the support upright having a plurality of spaced apart support plates, each support plate having a flat inlet end and an outlet end with a circular segment cutout, the circular segment cutout extending in the range of 160° to 230°.

2. The wafer cassette of claim 1, wherein each of the support plates is configured to hold an edge of a wafer during processing and allow a flow of gas to pass across a top surface of the wafer.

3. The wafer cassette of claim 2, wherein each of the circular segment cutouts are concentric with the wafer.

4. The wafer cassette of claim 1, wherein the plurality of spaced apart support plates are spaced equidistantly.

5. The wafer cassette of claim 4, wherein there are in the range of 5 to 25 support plates.

6. The wafer cassette of claim 1, wherein the support upright comprises opposing vertical column along a sidewall of the support plates.

7. The wafer cassette of claim 1, wherein the flat inlet end is spaced from an apex of the circular segment cutout by a distance less than or equal to 10 mm.

8. The wafer cassette of claim 1, wherein the top surface of the base plate has a recessed outer edge so that the support upright is positioned on a mesa.

9. The wafer cassette of claim 1, wherein the circular segment cutout extends in the range of 185° to 220°.

10. A vapor deposition processing chamber comprising:
a reaction chamber having a top wall, sidewalls with an inlet end and an outlet end, with an opening in a bottom wall; and
a wafer cassette comprising a base plate, and a support upright on a top surface of the base plate, the support upright having a plurality of spaced apart support plates, each support plate having a flat inlet end and an outlet end with a circular segment cutout, the circular segment cutout extending in the range of 160° to 230°,
wherein the base plate of the wafer cassette seals the opening in the bottom wall of the reaction chamber.

11. The vapor deposition processing chamber of claim 10, wherein each of the support plates is configured to hold an edge of a wafer during processing and allow a flow of gas to pass across a top surface of the wafer.

12. The vapor deposition processing chamber of claim 11, wherein each of the circular segment cutouts are concentric with the wafer.

13. The vapor deposition processing chamber of claim 10, wherein the plurality of spaced apart support plates are spaced equidistantly.

14. The vapor deposition processing chamber of claim 13, wherein there are in the range of 5 to 25 support plates.

15. The vapor deposition processing chamber of claim 10, wherein the support upright comprises opposing vertical column along a sidewall of the support plates.

16. The vapor deposition processing chamber of claim 10, wherein the flat inlet end is spaced from an apex of the circular segment cutout by a distance less than or equal to 10 mm.

17. The vapor deposition processing chamber of claim 10, wherein the top surface of the base plate has a recessed outer edge so that the support upright is positioned on a mesa.

18. The vapor deposition processing chamber of claim 17, wherein the base plate is sized so that the recessed outer edge forms a seal with a bottom surface of the bottom wall of the reaction chamber.

19. A method of improving gas flow uniformity is a cross-flow batch processing chamber, the method comprising:
positioning a wafer cassette into the processing chamber, the wafer cassette comprising a base plate, and a support upright on a top surface of the base plate, the support upright having a plurality of spaced apart support plates, each support plate having a flat inlet end and an outlet end with a circular segment cutout, the circular segment cutout extending in the range of 160° to 230°; and
flowing a process gas from an inlet of the processing chamber across through a gap between the spaced apart support plates to an outlet of the processing chamber.

20. The method of claim 19, wherein the gas flow uniformity is greater than with a similar processing chamber using a wafer cassette in which the spaced apart support plates do not have the flat inlet end.
